(19) United States
(12) Patent Application Publication
(10) Pub. No.: US 2026/0231501 A1
(43) Pub. Date: Aug. 6, 2026

(54) DIODE, RECTIFIER CIRCUIT USING SAME, AND POWER-RECEIVING RECTENNA

(71) Applicant: NICHIA CORPORATION, Anan-shi (JP)

(72) Inventors: Yuji OMAKI, Yokohama-shi (JP); Shusuke KAKIZAWA, Yokohama-shi (JP)

(73) Assignee: NICHIA CORPORATION, Anan-shi (JP)

(21) Appl. No.: 19/151,973

(22) PCT Filed: Jan. 29, 2024
(86) PCT No.: PCT/JP2024/002688

§ 371 Date: Jul. 29, 2025

(30) Foreign Application Priority Data
Jan. 31, 2023 (JP) 2023-013629

(51) Int. Cl. H10D 64/23; H10D 8/00; H10D 62/85

(52) U.S. Cl. CPC H10D 64/23; H10D 8/411; H10D 62/8503

(57) ABSTRACT

A diode includes a substrate, a first semiconductor layer provided on the substrate and containing a first impurity at a first concentration, a second semiconductor layer provided on the first semiconductor layer and containing a second impurity at a concentration lower than the first concentration, a first electrode provided on the first semiconductor layer and surrounding at least a part of the second semiconductor layer, and a second electrode provided on the second semiconductor layer. A width of the first electrode is in a range from one to six times a propagation length Lt [m] defined by Equation (1): Lt=(ρC [Ω·m2]/RS [Ω/sq])1/2 (1)

where ρC is a contact resistivity between the first semiconductor layer and the first electrode, and RS is a sheet resistance of the first semiconductor layer.

### CROSS-REFERENCE TO RELATED APPLICATIONS

This is a national stage of PCT Application No. PCT/JP2024/002688, filed on Jan. 29, 2024, which claims priority to Japanese Patent Application No. 2023-013629, filed on Jan. 31, 2021.

### TECHNICAL FIELD

The present disclosure relates to a diode, a rectifier circuit using the diode, and a power-receiving rectenna.

### BACKGROUND

There is an increasing demand for the supply of wireless power to mobile objects such as drones and devices such as smartphones, environmental sensors, and industrial sensors. For a wireless power transmission system, an electromagnetic wave system having a relatively long transmission distance has been developed. For example, gallium nitride (GaN) and gallium oxide (Ga₂O₃), both known as wide-bandgap semiconductors, are expected as rectifying diodes suitable for high-power and high-breakdown voltage power transmission. A diode in which a GaN-based semiconductor is used and an anode electrode is divided into a large number of circular electrodes is known (for example, see Japanese Patent Publication No. 5678341).

### SUMMARY

In order to implement high power conversion efficiency in power transmission, a time constant serving as an index of a delay time needs to be made as small as possible. An object of the present disclosure is to provide a diode in which a product of a capacitance C and a resistance R (hereinafter, referred to as a “CR product”) representing a time constant is reduced, a rectifier circuit using this diode, and a power-receiving rectenna.

In one embodiment, a diode includes:
a substrate;
a first semiconductor layer provided on the substrate, the first semiconductor layer containing a first impurity at a first concentration;
a second semiconductor layer provided on the first semiconductor layer, the second semiconductor layer containing a second impurity at a concentration lower than the first concentration;
a first electrode provided on the first semiconductor layer, the first electrode surrounding at least a part of the second semiconductor layer; and
a second electrode provided on the second semiconductor layer,
wherein a width of the first electrode is in a range from one time to six times a propagation length Lₜ [m] as defined by Equation (1) set forth below:

$${L}_{t} [ m ] = {( ρc [ Ω \cdot {m}^{2} ] / Rs [ Ω / sq ] )}^{1 / 2} \qquad ( 1 )$$

where ρ_{C} is a contact resistivity between the first semiconductor layer and the first electrode, and R_{S} is a sheet resistance of the first semiconductor layer.

A diode with a reduced CR product, a rectifier circuit using the diode, and a power-receiving rectenna are implemented.

### BRIEF DESCRIPTION OF DRAWINGS

FIG. 1 is a schematic view of an upper surface and a cross section of a diode of an embodiment.

FIG. 2 is a schematic cross-sectional view of an entire diode including a pad electrode and a wiring.

FIG. 3 is a figure illustrating an example of a diode arrangement on a substrate.

FIG. 4 is a diagram schematically illustrating a propagation length Lₜ, a contact resistivity ρ_{C}, and a sheet resistance R_{S}.

FIG. 5 is a scanning electron microscope image of a sample prepared for measurement.

FIG. 6 is a graph illustrating the relationship among a cathode electrode width, electrical resistance, and capacitance, and a linear approximation of the capacitance as a function of the cathode electrode width.

FIG. 7 is a graph illustrating the relationship between a cathode electrode width and a CR product.

FIG. 8 is a graph illustrating the relationship between a cathode electrode width and a contact resistance R_{C}.

FIG. 9 is a graph illustrating the relationship between a cathode electrode width and a CR_{C} product.

FIG. 10 is a graph illustrating the relationship between a cathode electrode width normalized by a propagation length and a CR_{C} product.

FIG. 11A is a schematic top view illustrating an example of an arrangement of diodes of an embodiment.

FIG. 11B is a schematic top view illustrating an arrangement of diodes of a reference example.

FIG. 11C is a schematic cross-sectional view illustrating an arrangement of diodes of an embodiment.

FIG. 12 is a scanning electron microscope image of a bridge structure on an anode side.

FIG. 13 is a schematic view of a connecting portion of a bridge wiring.

FIG. 14 is a view illustrating a shape maintaining effect of a connecting portion of a bridge wiring.

FIG. 15A is a manufacturing process view of a bridge wiring.

FIG. 15B is a manufacturing process view of a bridge wiring.

FIG. 15C is a manufacturing process view of a bridge wiring.

FIG. 15D is a manufacturing process view of a bridge wiring.

FIG. 15E is a manufacturing process view of a bridge wiring.

FIG. 15F is a manufacturing process view of a bridge wiring.

FIG. 15G is a manufacturing process view of a bridge wiring.

FIG. 15H is a manufacturing process view of a bridge wiring.

FIG. 16 is a schematic diagram of a power-receiving rectenna using a rectifier circuit to which the diode of an embodiment is applied.

### DETAILED DESCRIPTION

Embodiments of the present disclosure are described below with reference to the drawings. The following description is intended to embody technical concepts of the present disclosure, and the present disclosure is not limited to the following description unless specifically stated. In each drawing, members having identical functions may be denoted by the same reference characters to minimize redundant description. In consideration of explanation of main points or ease of understanding, embodiments may be illustrated separately. Partial substitutions or combinations of the configurations illustrated in different embodiments or examples can be made. In embodiments to be described below, differences from the embodiment(s) described before are mainly described, and redundant descriptions of commonalities with the embodiment(s) described before may be omitted. The size, positional relationship, and the like of members illustrated in the drawings may be exaggerated in order to clarify explanation.

### Basic Structure of Diode

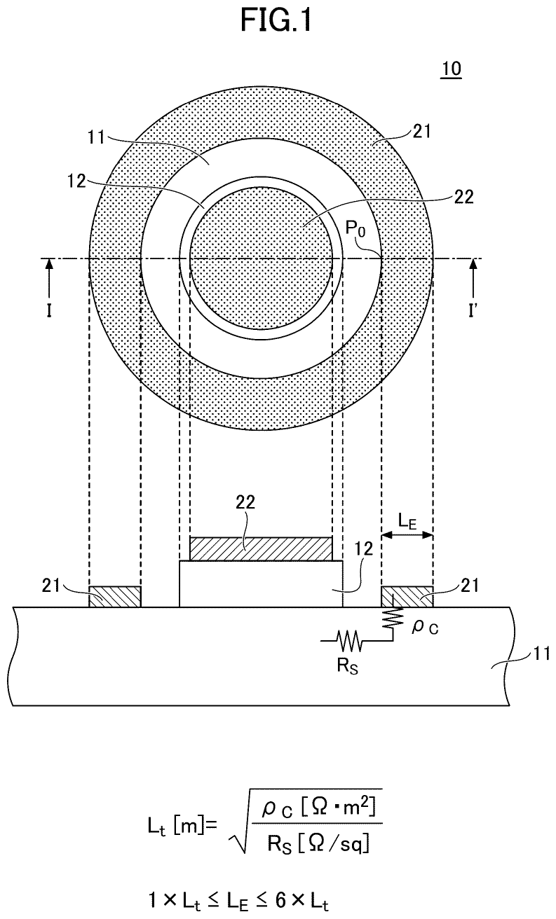

FIG. 1 is a schematic view of a part of an upper surface of a diode 10 of an embodiment and a cross section taken along the line I-I′. The diode 10 includes a first semiconductor layer 11 containing a first impurity at a first concentration, a second semiconductor layer 12 provided on the first semiconductor layer 11 and containing a second impurity at a concentration lower than the first concentration, a first electrode 21 provided on the first semiconductor layer 11 and surrounding at least a part of the second semiconductor layer 12, and a second electrode 22 provided on the second semiconductor layer 12. When a contact resistivity between the first semiconductor layer 11 and the first electrode 21 is defined as ρ_{C} [Ω·m²], and a sheet resistance of the first semiconductor layer 11 is defined as R_{S} [Ω/sq], a width of the first electrode 21, which is a distance between an inner wall and an outer wall of the first electrode 21, is in a range from one time to six times a propagation length Lₜ [m], which is defined by the following Equation (1) where the propagation length Lₜ is defined when the shape of electrode is rectangular.

$${L}_{t} [ m ] = {( ρc [ Ω \cdot {m}^{2} ] / Rs [ Ω / sq ] )}^{1 / 2} \qquad ( 1 )$$

### First Semiconductor Layer 11 and Second Semiconductor Layer 12

The first semiconductor layer 11 and the second semiconductor layer 12 may be formed of a group III-V compound semiconductor such as a GaN-based semiconductor, an InP-based semiconductor, or a GaAs-based semiconductor, Si, SiC, Ga₂O₃, Al₂O₃, or diamond. These compound semiconductor materials may be a binary compound system, a ternary compound system, or a quaternary compound system. The first semiconductor layer 11 and the second semiconductor layer 12 preferably use a GaN-based semiconductor, which is a nitride semiconductor. Because GaN-based semiconductors, SiC, Ga₂O₃, and Al₂O₃ have a wide band gap, they have a high withstand electric field. Thus, an element having a low resistance and a high breakdown voltage can be made smaller. Consequently, a diode having a small capacitance and a small CR product can be produced. The shape of the first semiconductor layer 11 and the second semiconductor layer 12 in top view may be a circle, an ellipse, or a polygon.

The materials of the first impurity contained in the first semiconductor layer 11 and the second impurity contained in the second semiconductor layer 12 may be the same, or different. The first impurity and the second impurity may be n-type impurities or p-type impurities. The first impurity and the second impurity are preferably n-type impurities. Thus, the resistance of the first semiconductor layer 11 and the second semiconductor layer 12 can be reduced. For example, when a GaN-based semiconductor is used, Si, Ge, Mg, or the like may be used as the first impurity and the second impurity. When an InP-based semiconductor is used, Sn, Zn, or the like may be used as the first impurity and the second impurity. When a GaAs-based semiconductor is used, Si, Sn, S, Se, Te, or the like may be used as the first impurity and the second impurity. When Si, SiC, and diamond are used, N, P, As, Sb, B, and Al may be used.

The concentration of the first impurity of the first semiconductor layer 11 is higher than the concentration of the second impurity of the second semiconductor layer 12. The concentration of the first impurity may be greater than one time and not greater than 200000 times the concentration of the second impurity, preferably in a range from five times to 50 times the concentration of the second impurity. The concentration of the first impurity may be, for example, in a range from 1×10²⁴ m⁻³ to 1×10²⁸ m⁻³, preferably in a range from 1×10²⁵ m⁻³ to 1×10²⁷ m⁻³. Thus, the sheet resistance R_{S} of the first semiconductor layer 11 is reduced and the contact resistivity ρ_{C} with the first electrode 21 is reduced, so that the flow of current from the first semiconductor layer 11 to the first electrode 21 is facilitated. On the other hand, the second semiconductor layer 12 contains the second impurity at a concentration lower than the first impurity in order to maintain a reverse breakdown voltage. The concentration of the second impurity is lower than the concentration of the first impurity and may be, for example, in a range from 5×10²² m⁻³ to 5×10²⁴ m⁻³, preferably in a range from 1×10²³ m⁻³ to 1× 10²⁴ m⁻³.

### Second Electrode 22

On the second semiconductor layer 12, the second electrode 22 is provided in contact with the second semiconductor layer 12. The second electrode 22 is formed of a metal that can make Schottky contact with the second semiconductor layer 12 containing the second impurity having a lower concentration than the first impurity. When the second impurity is an n-type impurity, a Schottky barrier is formed between the second electrode 22 and the second semiconductor layer 12 by selecting a metal material having a larger work function than the second semiconductor layer 12. A metal material forming a Schottky barrier having a desired size in relation to the material used for the second semiconductor layer 12 is used. Thus, a Schottky barrier diode that allows only a current flowing from the second electrode 22 toward the second semiconductor layer 12 to pass therethrough is obtained. A Schottky barrier may be formed between the second electrode 22 and the second semiconductor layer 12 by using a p-type impurity as the second impurity and selecting a metal material having a smaller work function than the second semiconductor layer 12. The second impurity is preferably an n-type impurity. Thus, the electrical resistance of the second semiconductor layer 12 can be further reduced. In the following description, the second electrode 22 of the Schottky barrier diode is also referred to as an “anode electrode 22” and the first electrode 21 is also referred to as a “cathode electrode 21” in order to facilitate understanding of the description. The second electrode 22 contains at least one selected from the group consisting of Ni, Pt, and Au. The planar shape of the second electrode 22 may be a circular shape, an elliptical shape, a quadrangular shape, or any other polygonal shape.

### Cathode Electrode 21 (First Electrode 21)

The cathode electrode 21 is formed of a metal material that can make ohmic contact with the first semiconductor layer 11. The cathode electrode 21 contains at least one selected from the group consisting of Al, Ti, V, Pt, and Au. Because the first semiconductor layer 11 contains the first impurity at a high concentration, the work function of the metal material of the cathode electrode 21 does not have to be set lower than the work function of the first semiconductor layer 11. For example, the cathode electrode 21 is formed of aluminum (Al) having a low electrical resistance. The cathode electrode 21 may include a titanium (Ti) thin film that increases adhesion at an interface between the Al layer and the first semiconductor layer 11. The cathode electrode 21 may have a multilayer structure, and a plurality of metals may be contained in one layer.

The cathode electrode 21 surrounds at least a part of the second semiconductor layer 12. In the example of FIG. 1, the cathode electrode 21 surrounds the entire circumference of the second semiconductor layer 12. The planar shape of the cathode electrode 21 may be partially open like a C-shape; however, an annular shape as illustrated in FIG. 1 is desirably adopted from the viewpoint of reducing the bias of current. The shape surrounded by an inner lateral surface of the cathode electrode 21 and/or the shape surrounded by an outer lateral surface thereof may be, for example, a polygonal shape such as a triangular shape or a quadrangular shape; however, an annular shape as illustrated in FIG. 1 is desirably adopted from the viewpoint of suppressing a current from being concentrated on a corner portion of the polygonal shape. In addition, the planar shape of the cathode electrode 21 may be an ellipse. Alternatively, the cathode electrode 21 may have a planar shape in which an outer side is wider than a center. For example, the planar shape of the cathode electrode 21 may be a gourd.

The distance between the inner wall and the outer wall of the cathode electrode 21 is defined as a first electrode width L_{E}. This distance represents the distance between the inner wall and the outer wall in the direction perpendicular to the tangent line of the inner wall of the cathode electrode 21 in top view. Hereinafter, the first electrode width L_{E} is also referred to as a cathode electrode width L_{E} or simply as a width L_{E}. The cathode electrode width L_{E} is in a range from one time to six times the propagation length Lₜ [m] as defined by the above-described Equation (1). By setting the cathode electrode width L_{E} in this range, the CR product is kept small and favorable rectification characteristics are exhibited regardless of the material of the second semiconductor layer 12, the breakdown voltage design, the anode resistance design, and the like. In particular, when the diode is driven at a high frequency, the cathode electrode width L_{E} is desirably in the above-described range. The high frequency here includes a gigahertz band to a terahertz band being frequency bands for wireless communication. The diode 10 of the embodiment has rectification characteristics in a range from 0.9 GHz to 500 GHz, for example. In top view, the length of a portion of the inner wall in which the first electrode width L_{E} satisfies a range from one time to six times the propagation length Lₜ may be 70% or more, preferably 80% or more, more preferably 90% or more of the total length of the inner wall of the first electrode 21. Thus, a component of the CR product derived from the first electrode 21 (representing a CR_{C} product to be described below) can be efficiently reduced.

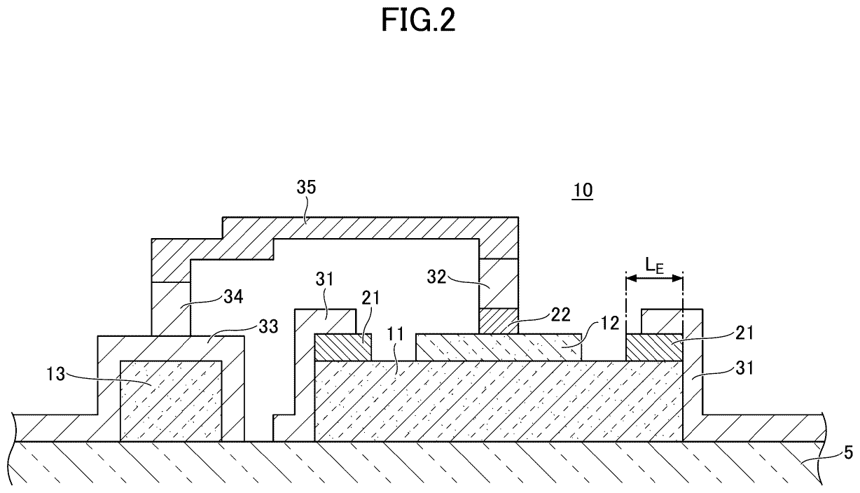

FIG. 2 is a schematic cross-sectional view of the entire diode 10 including a pad electrode and a wiring. In FIG. 2, the diode 10 is configured by forming the first semiconductor layer 11 and the second semiconductor layer 12 on a substrate 5. The substrate 5 is an insulating substrate formed of sapphire or the like, or a semi-insulating substrate formed of GaN, GaAs, SiC or the like with no impurities doped. The first semiconductor layer 11 and a third semiconductor layer 13 are formed on the substrate 5. The third semiconductor layer 13 is formed in a region on the substrate 5 in which the first semiconductor layer 11 is not provided and contains the same impurity as in the first semiconductor layer 11 at the same concentration. Each of the first semiconductor layer 11 and the third semiconductor layer 13 may be an n-type semiconductor layer in which the concentration of the first impurity is higher than that of the second semiconductor layer 12.

The diode 10 includes a pad electrode 31 disposed on an upper surface and a lateral surface of the cathode electrode 21 on the first semiconductor layer 11. The pad electrode 31 contains at least gold (Au). The pad electrode 31 may have a nickel (Ni) thin film on the interface side with the cathode electrode 21. The pad electrode 31 overlaps the cathode electrode 21 containing Al. Although different metals are layered on the upper surface of the cathode electrode 21, the cathode electrode 21 itself is an electrode having a width L_{E} determined by the propagation length Lₜ, and an area overlapping the pad electrode 31 is small. Consequently, diffusion of different metals, specifically, diffusion and mixing of Al and Au may be reduced.

A pad electrode 32 is provided on an upper surface of the anode electrode 22. A pad electrode 33 covers the upper surface and the lateral surface of the third semiconductor layer 13, and a pad electrode 34 is provided on the pad electrode 33. The pad electrodes 33 and 34 may also be referred to as “third electrodes”. A bridge wiring 35 electrically connects the anode electrode 22 to the pad electrodes 33 and 34 as the third electrodes. More specifically, the anode electrode 22 is connected to one end of the bridge wiring 35 via the pad electrode 32, and the third electrode including the pad electrode 33 and the pad electrode 34 is connected to the other end of the bridge wiring 35. The pad electrode 33 extends to an anode pad described below on the substrate 5, and the pad electrode 31 connected to the cathode electrode 21 extends to a cathode pad described below on the substrate 5. Note that the pad electrode 34 may be omitted. In this case, the bridge wiring 35 is directly connected to the pad electrode 33. A width of the bridge wiring 35 may be, for example, in a range from 2 μm to 7 μm.

By providing the pad electrodes 32 and 34, a height of the bridge wiring 35 can be increased to reduce the parasitic capacitance between the bridge wiring 35 and an electrode material of a lower layer. When the width L_{E} of the cathode electrode 21 determined by the propagation length Lₜ is set to be small within the above-described range, a length of the bridge wiring 35 can be shortened, and disconnection or short-circuit of the bridge wiring 35 and an increase in resistance can be reduced.

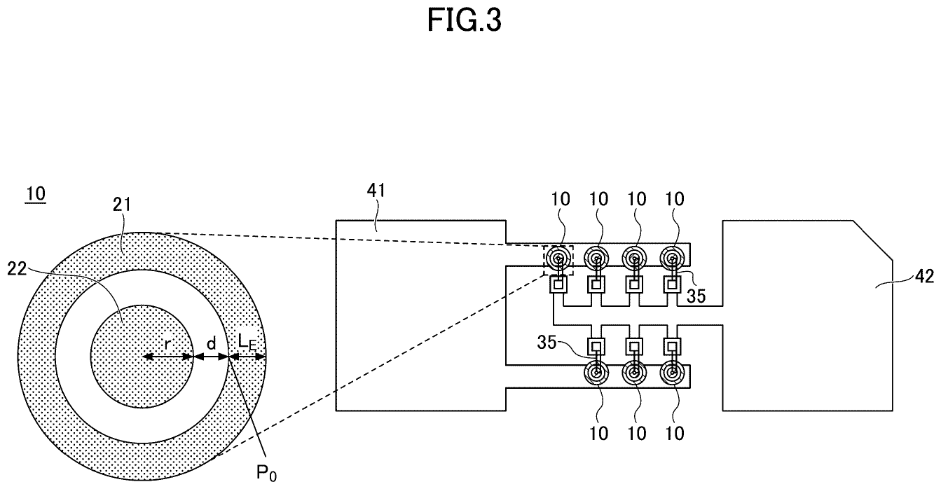

FIG. 3 illustrates an example of a diode arrangement on the substrate 5. A plurality of diodes may be connected in parallel. In this example, seven diodes 10 are connected in parallel. The cathode electrode 21 of each diode 10 is connected to a cathode pad 41, and the anode electrode 22 is connected to an anode pad 42 via the bridge wiring 35. In the example of FIG. 3, it is assumed that the radius of the anode electrode 22 is defined as r, the width of the cathode electrode 21 is L_{E}, and the distance between the anode electrode 22 and the cathode electrode 21 is d. For example, when the radius r of the anode electrode 22 is 2 μm and the distance dis 1 μm, the cathode electrode 21 having an inner diameter of 6 μm and a width L_{E} surrounds the anode electrode 22 having a diameter of 4 μm. At this time, the capacitance C between the anode electrode 22 and the cathode electrode 21 is, for example, about 0.2 pF.

### Distributed Constant Circuit Model

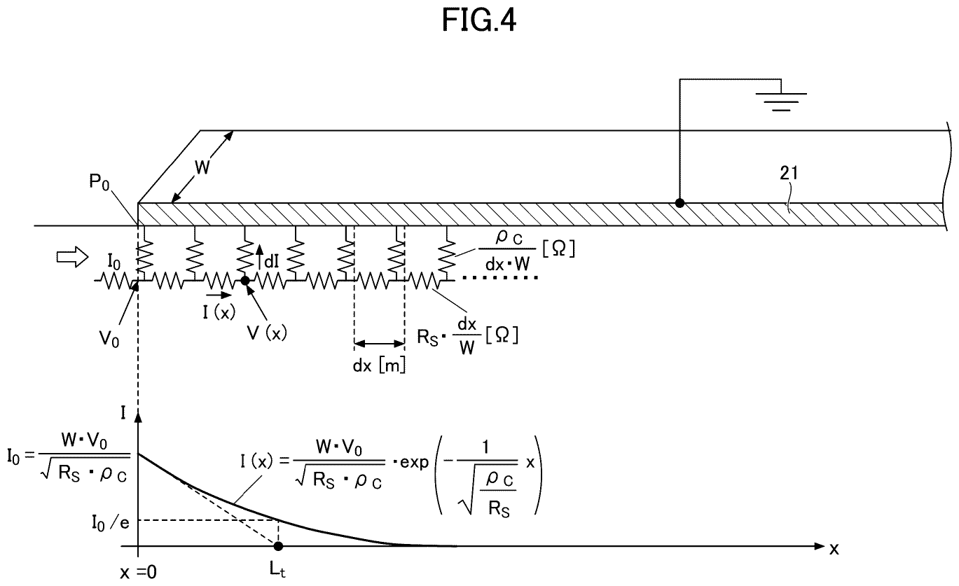

FIG. 4 is a model of a distributed constant circuit when the shape of the electrode is assumed to be rectangular. FIG. 4 schematically illustrates the propagation length Lₜ, the contact resistivity ρ_{C}, and the sheet resistance R_{S}. It is assumed that a position in the width direction from a position P₀ on a side close to the anode of the cathode electrode is defined as x. It is assumed that a current flowing from the anode electrode to the cathode electrode at a position P₀ is I₀ and a voltage is V₀. A contact resistance R_{C} [Ω] at the position P₀ is represented by V₀/I₀.

The contact resistance R_{C} of the cathode electrode 21 is considered to be a ladder-like combination of a minute sheet resistance R_{S}·ds/W [Ω] in a direction parallel to the interface between the cathode electrode 21 and the first semiconductor layer 11 and a minute contact resistivity ρ_{C}/(dx·W) [Ω] in a direction perpendicular to this interface. The sheet resistance is the resistance of the first semiconductor layer 11 to which a current flowing parallel to the interface is applied. The contact resistivity is a contact resistance per unit area (1 m²), when a current flows in the direction perpendicular to the interface. The contact resistance R_{C} in the entire width L_{E} direction of the cathode electrode 21 is represented by the following Equation (4) by simultaneously solving the following Differential Equations (2) and (3) regarding a current flowing through a minute sheet resistance R_{S}·dx/W [Ω] and a minute contact resistivity ρ_{C}/(dx·W) [Ω], and a voltage applied thereto.

$$- dV ( x ) / dx = I ( x ) \cdot Rs / W \qquad ( 2 )$$

$$- dI ( x ) / dx = V ( x ) \cdot W / ρ c \qquad ( 3 )$$

$$Rc = {( Rs \cdot ρ c )}^{1 / 2} / W \qquad ( 4 )$$

Note that V(x) and I(x) are a voltage and a current at the position x. In addition, W is the thickness of the cathode electrode orthogonal to the width direction and is a constant. In this example, because a DC circuit is assumed, capacitance and inductance were ignored. That is, the differential equations were solved using real parts of distributed series impedance and distributed parallel admittance.

The current I₀ at the position P₀ is attenuated by an amount corresponding to the sheet resistance and the contact resistivity up to the position x while reaching the position x. The attenuation of the current I(x) is represented by an exponential function illustrated in FIG. 4.

The current I(x) is represented by the following Equation (5).

$$I ( x ) = W \cdot {V}_{0} \cdot {( Rs \cdot pc )}^{- 1 / 2} \cdot exp \{ - x \cdot {( ρ c / Rs )}^{- 1 / 2} \} \qquad ( 5 )$$

The distance x at which the current I (x) is 1/e times the current I₀, that is, the propagation length Lₜ is represented by:

$${L}_{t} [ m ] = {( ρc [ Ω \cdot {m}^{2} ] / Rs [ Ω / sq ] )}^{1 / 2} \qquad ( 1 )$$

The propagation length Lₜ is defined in the rectangular model in this way.

Subsequently, a distributed constant circuit when an actual shape of the electrode is cylindrical is considered. First, the contact resistance and capacitance of an actual diode were examined.

### Measurement and Evaluation of CR Product

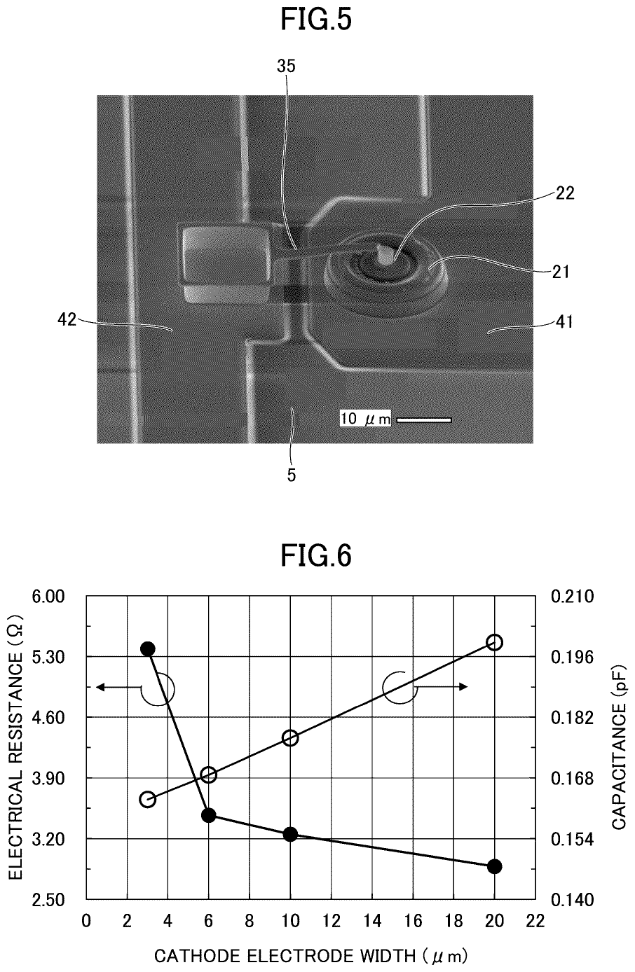

FIG. 5 is a scanning electron microscope (SEM) image of a sample formed on the substrate 5 for measurement. The diameter of the anode electrode 22 is 4 μm, the inner diameter of the cathode electrode 21 is 6 μm, and the distance d (see FIG. 3) from the circumference of the anode electrode 22 to the inner lateral surface of the cathode electrode 21 is 1 μm. Four types of samples were prepared by changing the design value of the width L_{E} of the cathode electrode 21 in a radial direction to 3 μm, 6 μm, 10 μm, and 20 μm, and the capacitance C of each sample was measured by an LCR meter, and the resistance R was measured by a semiconductor parameter analyzer. Each sample is the result of four diodes connected in parallel.

A graph connected by a solid line in FIG. 6 illustrates a relationship between the cathode electrode width L_{E} [μm], the electrical resistance R [Ω], and the capacitance C [pF]. A graph connecting plots of black circles indicates a change in the electrical resistance R, and a graph connecting plots of white circles indicates a change in the capacitance C. When the cathode electrode width L_{E} is increased, the capacitance C tended to increase and the electrical resistance R tended to decrease. Because a contact area between the cathode electrode and the first semiconductor layer 11 increases as the cathode electrode width increases, the electrical resistance was expected to decrease. On the other hand, although it is generally assumed that the cathode electrode width L_{E} does not contribute to an increase in capacitance, a tendency that the capacitance increases as the cathode electrode width increases was obtained in this experiment. Such an increase in the capacitance is assumed to be caused by, for example, a capacitance component that is coupled to a leakage component of the first semiconductor layer as the distance from the anode electrode increases in top view. In FIG. 6, the result of the cathode electrode width L_{E} of 3 μm is the result of the sample in which the cathode electrode is provided only on the first semiconductor layer 11. The results obtained when the design values of the cathode electrode width L_{E} were 6 μm, 10 μm, and 20 μm represent the average values of six samples produced. Subsequently, the CR product is plotted based on the measurement data of FIG. 6.

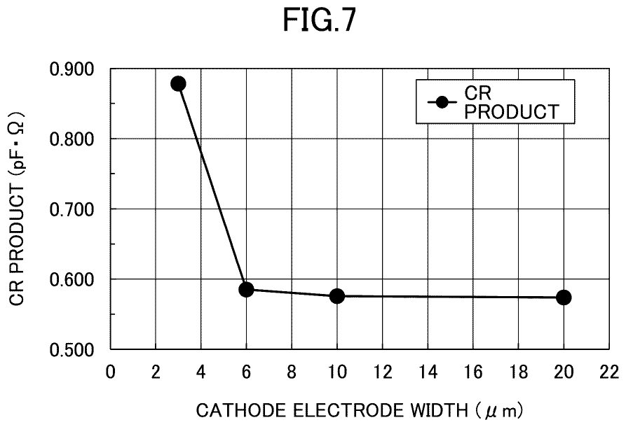

FIG. 7 illustrates the relationship between the cathode electrode width L_{E} [μm] and the CR product [pF·Ω]. As illustrated in FIG. 6, because the tendency of increase and decrease in the electrical resistance and the tendency of increase and decrease in the capacitance are opposite to each other, it was expected that there is a cathode electrode width at which the CR product takes a minimum value. However, this result is a result obtained from a specific sample. The cathode electrode width L_{E} [μm] that minimizes the CR product may vary depending on the design. In order to calculate the CR product with various design values, the capacitance C is formulated. On the basis of the measurement results of FIG. 6, the capacitance C is obtained as a function of the cathode electrode width L_{E}.

The results of FIG. 6 were used to obtain a linear approximation of the capacitance C as the function of the cathode electrode width L_{E}. However, because a numerical calculation to be described below is a calculation result when seven diodes are connected in parallel, the value of the capacitance illustrated in FIG. 6 is multiplied by 7/4 to obtain a linear approximation when the number of parallel diodes is converted from four to seven. The obtained approximate expression is as follows:

$$C = 0.0038 \times {L}_{E} + 0.2731 \qquad ( 6 )$$

The capacitance C is represented as the function of the cathode electrode width L_{E} in Equation (6). By substituting a desired cathode electrode width L_{E}, the capacitance C at that time is obtained. Subsequently, the contact resistance R_{C} is numerically calculated.

### Numerical Calculation

Table 1 indicates design examples in which the sheet resistance R_{S} and the contact resistivity ρc are changed. The following conditions were set for the propagation lengths Lₜ of 1.5 μm, 3 μm, 6 μm, and 10 μm. That is, the inner diameter of the cathode electrode 21 was fixed to 6 μm. The sheet resistance R_{S} was set to two values, 11.11 [Ω/sq] and 20 [Ω/sq]. The contact resistivity ρ_{C} [Ωm²] is determined in four values from the definitional equation of the propagation length Lₜ. Consequently, a total of eight design patterns A1, A2, B1, B2, C1, C2, D1, and D2 were set. Note that Rₛ and ρ_{c} are quantities inherent to materials and device conditions, and therefore do not depend on the shape of the electrode. Consequently, the values of the sheet resistance Rₛ and the contact resistivity ρ_{C} assumed from the propagation length Lₜ defined in the rectangular model can also be applied to a cylindrical model.

TABLE 1

| | | Cathode | | | Propagation |
|---|---|---|---|---|---|
| | | inner | Sheet | Contact | length Lₜ [μm] |
| | | diameter | resistance | resistivity | (rectangular |
| Sample | Legend | [μm] | Rs [Ω/sq] | ρc [Ωm²] | model) |
| A1 | ● | 6 | 20 | 4.50 × 10⁻¹¹ | 1.5 |
| A2 | ◯ | 6 | 11.11 | 2.50 × 10⁻¹¹ | 1.5 |
| B1 | ♦ | 6 | 20 | 1.80 × 10⁻¹⁰ | 3 |
| B2 | ⋄ | 6 | 11.11 | 1.00 × 10⁻¹⁰ | 3 |
| C1 | ▴ | 6 | 20 | 7.20 × 10⁻¹⁰ | 6 |
| C2 | Δ | 6 | 11.11 | 4.00 × 10⁻¹⁰ | 6 |
| D1 | ▪ | 6 | 20 | 2.00 × 10⁻¹⁰ | 10 |
| D2 | □ | 6 | 11.11 | 1.11 × 10⁻¹⁰ | 10 |

The differential equation was solved numerically assuming a cylindrical electrode. This is because the distributed constant circuit model can be usually solved analytically when a rectangular electrode is assumed as described with reference to FIG. 4, but is not analytically solved when a cylindrical electrode model is assumed. Differential Equations (7) and (8) for current and voltage are as follows:

$$- dV ( x ) / dx = I ( x ) \cdot Rs / ( 2 π \cdot x ) \qquad ( 7 )$$

$$- dI ( x ) / dx = V ( x ) \cdot ( 2 π \cdot x ) / ρ c \qquad ( 8 )$$

A portion corresponding to W in the differential equation described with reference to FIG. 4 is 2 π·X. The values listed in Table 1 were used for R_{S} and ρc.

First, as initial conditions, I (3μ) and V (3μ) were set as I (x) and V (x). “3μ” is a distance from the center of the cylinder to the end of the inner wall of the cathode electrode and is half the value of inner diameter of 6 μm. The current spreads radially from this position. I (3μ) was assumed to be 10 mA. V (3μ) was set to such a value that the current value substantially does not become negative when the position x has a sufficiently large value. This may be assumed to be V (3μ) such that the current value substantially does not become negative when the calculation is repeated until x=100μ in the calculation process to be described below. V (3μ) is a voltage used to determine the contact resistance R_{C} and is finally corrected as described below.

When x=3μ, the calculation results of the right-hand sides of Equations (7) and (8) are obtained from the above-described assumption. That is, the left-hand sides of Equations (7) and (8) described above are obtained.

Subsequently, values obtained by shifting x by 0.01 μm, that is, V (3.01 μm) and I (3.01 μm) at x=3.01 μm are obtained. The following were calculated using the left-hand sides of Equations (7) and (8):

$$\begin{matrix}V ( 3.01 μ ) = V ( 3 μ ) + ( dV ( x ) / dx ) \cdot 0.01 \\ I ( 3.01 μ ) = I ( 3 μ ) + ( dI ( x ) / dx ) \cdot 0.01\end{matrix}$$

That is, V (3.01μ) and I (3.01μ) are obtained by adding V (3μ) and I (3μ) determined from the initial conditions and the amount of change thereof.

Subsequently, V (3.02μ) and I (3.02·μ) at x=3.02μ are obtained in the same manner. This is repeated up to the position of the outer wall of the cathode electrode. Note that dV (x)/dx and dI (x)/dx are amounts that change depending on the position x.

In the above-described calculations, V (3μ) is an assumed value and needs to be corrected. The correction for V (3μ) uses boundary conditions. That is, the fact that substantially no current flows in the radial direction at the end of the cathode electrode width is used. In the calculation, because I=0 is not possible to establish, I=1 [μA] was assumed at the end of the electrode. 1 μA is sufficiently smaller than the assumed initial current value of 10 mA. When the calculation does not converge under the condition of the current value, the electrical resistance at the cathode electrode end may be assumed to increase. For example, the electrical resistance may be 1×10¹⁰[Ω] at the end of the electrode. The above-described calculation process is repeatedly performed while changing V (3μ) to search for the initial value V (3μ) satisfying the boundary conditions when the position x is the position of the outer wall of the electrode. When V (3μ) satisfying the boundary conditions is obtained, the contact resistance R_{C} is obtained by calculating V (3μ)/I (3μ). Note that V (3μ)/I (3μ) does not depend on the initial value. In addition, when the value of the current or the electrical resistance at the position x at which the boundary conditions are defined is within a range of ±10% of the set value, the calculation may be ended at that value. Because the result obtained by the calculation corresponds to one diode, when seven diodes are connected in parallel, this value may be divided by 7. In this way, the contact resistance R_{C} of the diode when the number of diodes connected in parallel is 7 is obtained.

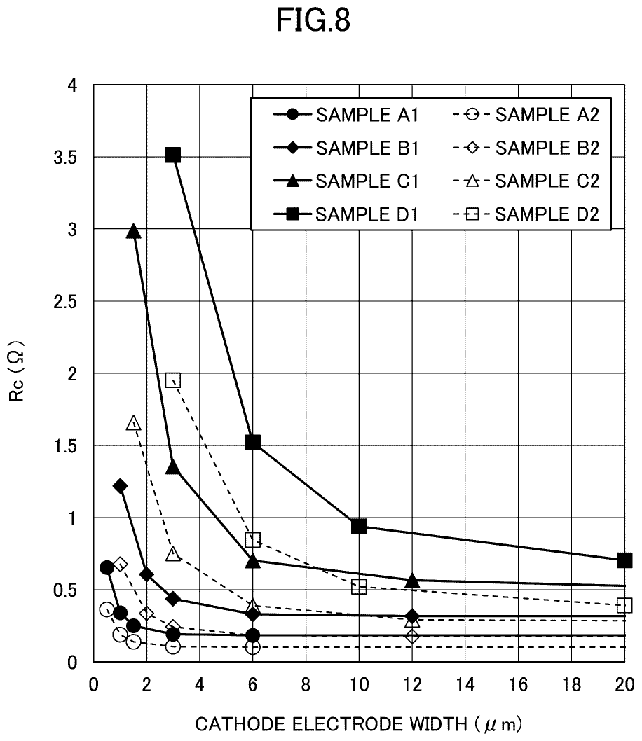

FIG. 8 illustrates the relationship between the cathode electrode width L_{E} and the contact resistance R_{C} by numerical calculation. As the cathode electrode width L_{E} increases, the contact resistance R_{C} decreases. As indicated in the design patterns A1, A2, B1, and B2, when the value of the contact resistivity ρ_{C} is smaller (see FIG. 8), the contact resistance R_{C} is saturated at the smaller cathode electrode width L_{E} and the contact resistance R_{C} is smaller. When the designs of the first semiconductor layer 11, the second semiconductor layer 12, and the anode electrode 22 are the same, the resistance of the diode 10 varies with the contact resistance R_{C}. Subsequently, how the CR product (referred to as “CR_{C} product” for convenience) of the capacitance C and the contact resistance R_{C} of the cathode electrode changes is examined.

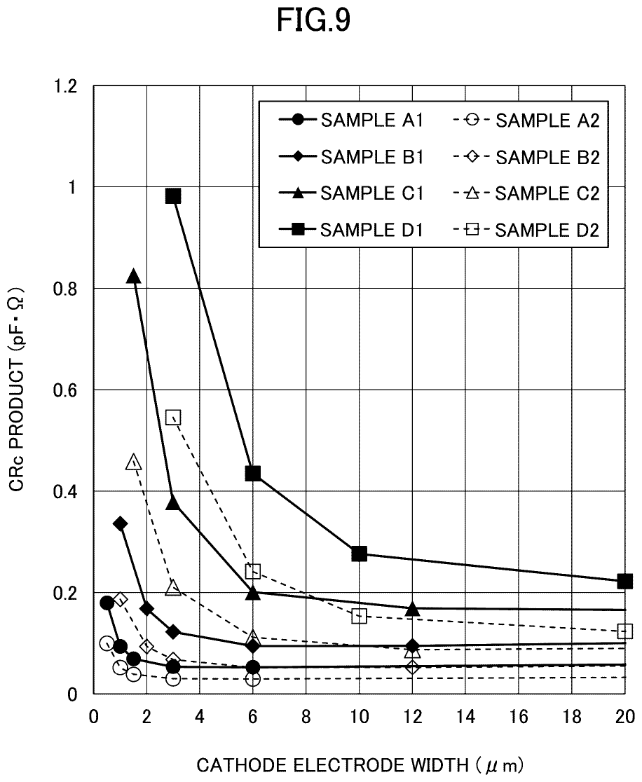

FIG. 9 illustrates the relationship between the cathode electrode width L_{E} and the CR_{C} product. For the capacitance C, the value of Equation (4) as obtained by the linear approximation is used. From FIG. 9, the cathode electrode width L_{E} at which the CR_{C} product is minimized was expected to be different for each design. Regardless of the design, a suitable cathode electrode width L_{E}, that is, a cathode electrode width L_{E}, at which the CR_{C} product takes a minimum value or a value in the vicinity thereof, needs to be defined.

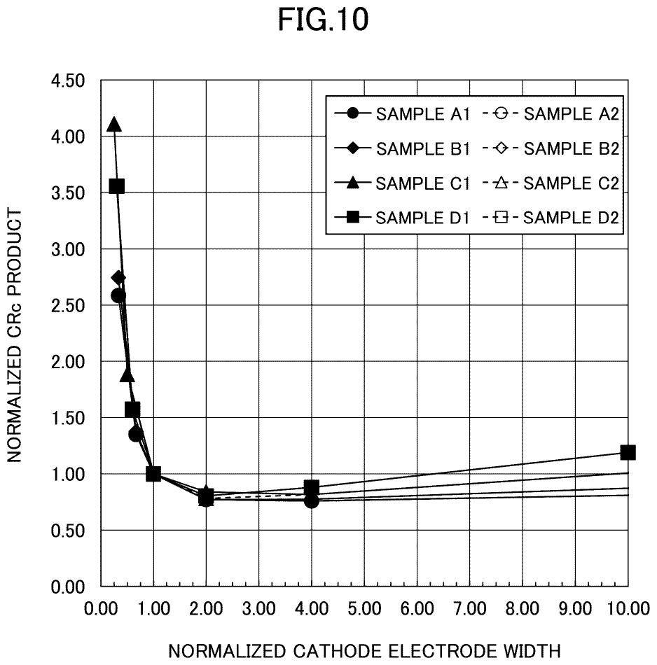

FIG. 10 illustrates the relationship between a cathode electrode width L_{E} normalized by the propagation length Lₜ and a CR_{C} product normalized by a CR_{C} product when the normalized cathode electrode width L_{E} is 1. The horizontal axis represents the cathode electrode width L_{E} normalized by the propagation length Lₜ, and the vertical axis represents the CR_{C} product normalized by the CR_{C} value when L_{E}=Lₜ. Note that, because the propagation length Lₜ is not analytically obtained in the cylindrical electrode, the CR_{C} product is minimum in the case in which L_{E}=2×Lₜ to 4×Lₜ if normalized by the propagation length Lₜ obtained by the rectangular model. When the cathode electrode width L_{E} is in a range from 1×Lₜ to 6×Lₜ, the normalized CR_{C} value can be made 1 or less. When the cathode electrode width L_{E} is in a range from 1.5×Lₜ to 5×Lₜ, the normalized CR_{C} value can be made 0.95 or less. When the cathode electrode width L_{E} is in a range from 1.8×Lₜ to 4.2×Lₜ, the normalized CR_{C} value can be made 0.9 or less. When the cathode electrode width L_{E} is in a range from 2×Lₜ to 4×Lₜ, the normalized CR_{C} value can be made 0.88 or less. Consequently, the width of the first electrode (cathode electrode) is preferably in a range from 1.5 times to 5 times, in a range from 1.8 times to 4.2 times, or in a range from 2 times to 4 times the propagation length Lₜ. Thus, the CR_{C} product can be reduced. Consequently, the CR product can be reduced.

Even when the inner diameter of the cathode electrode 21 is set to a value different from 6 μm and the same numerical calculation as that in FIGS. 8 and 9 is performed, it is confirmed that the result with the same tendency as that in FIG. 10 is obtained. For this reason, the width of the cathode electrode 21 of the diode 10 according to the embodiment is set in a range from one time to six times the propagation length Lₜ defined by Equation (1). By setting the width of the cathode electrode 21 in this range, the CR_{C} product can be maintained at a minimum or in the vicinity thereof, and good rectification characteristics are obtained in a high-frequency band, in particular, in a range from 0.9 GHz to 500 GHz. For example, in a frequency band lower than the high-frequency band, a resistance value is large with respect to a change in capacitance, and the CR product is less problematic.

The propagation length Lₜ used in the description provided above is a parameter that can be designed from the sheet resistance R_{S} and the contact resistivity ρc obtained based on a transmission line model (TLM) method.

When the propagation length Lₜ is estimated from the diode, for example, the following method can be used. First, the sheet resistance R_{S} can be obtained by performing a Hall measurement on the diode. For an electrode used for the Hall measurement, an electrode provided in the diode is removed and four terminals are newly provided. Subsequently, an approximate value of the contact resistivity ρc can be estimated from the slope of I-V characteristics. The range of the cathode electrode width L_{E} may be determined with respect to the range of the propagation length estimated from these values.

The contact resistivity ρ_{C} may be determined by measuring the dependence of the electrical resistance on the cathode electrode width. For example, the contact resistivity ρ_{C} may be determined from the electrical resistance at each width while reducing the cathode electrode width by a focused ion beam or the like.

### Other Effects of Configuration

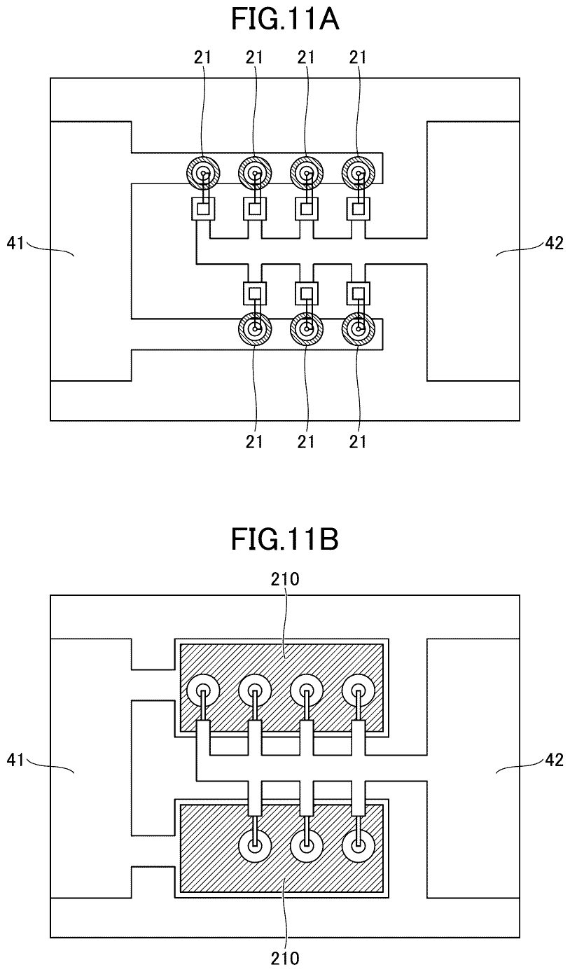

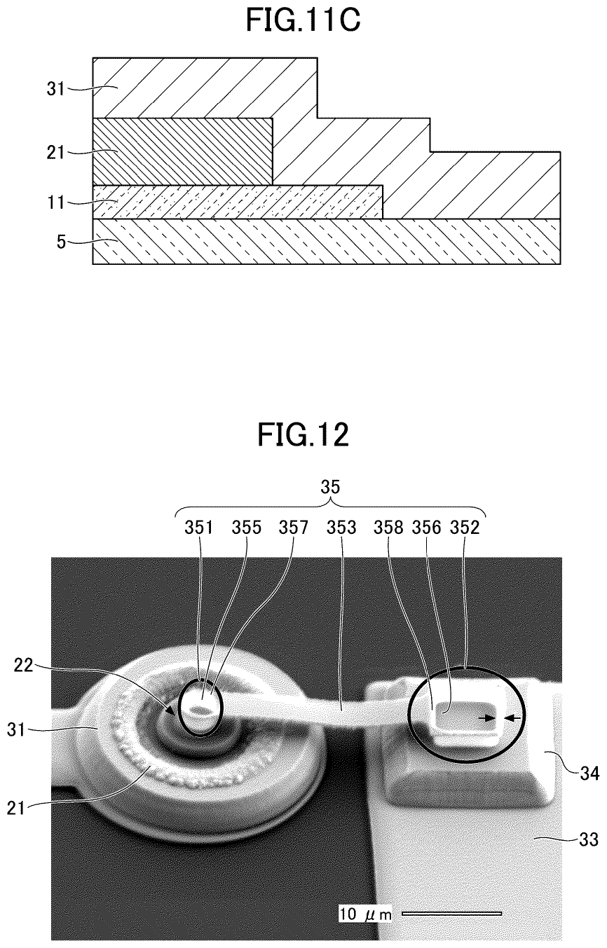

FIG. 11A is a schematic top view illustrating an example of an arrangement of the diodes 10 according to the embodiment. FIG. 11B is a schematic view of a configuration in which common cathode electrodes 210 having a large area are used in the same anode arrangement as FIG. 11A. FIG. 11C is a cross-sectional view illustrating a state in which the pad electrodes 31 cover the upper surface and lateral surfaces of the cathode electrode. The effect of reducing metal diffusion by the configuration of the cathode electrode 21 according to the embodiment is described with reference to FIGS. 11A, 11B, and 11C.

An electrode material is selected in accordance with the material of the first semiconductor layer 11 so that the electrical resistance decreases. However, the electrical resistance may increase due to diffusion or migration of the electrode material. In the example illustrated in FIG. 11C, the cathode electrode 21 or the common cathode electrode 210 is provided on the first semiconductor layer 11 on the substrate 5, and the pad electrode 31 covers the upper surface and the lateral surface of the cathode electrode 21 or the common cathode electrode 210. The cathode electrode 21 and the common cathode electrode 210 are formed of the same material and have the same thickness, but have different planar areas. In the models of FIGS. 11A and 11B, each of the cathode electrode 21 and the common cathode electrode 210 includes a Ti layer having a thickness of 10 nm and an Al layer having a thickness of 300 nm on the Ti layer. The pad electrode 31 overlapping the cathode electrode 21 and the common cathode electrode 210 includes a Ni layer having a thickness of 10 nm and an Au layer having a thickness of 500 nm on the Ni layer. The pad electrode 31 is connected to the cathode pad 41.

In the common cathode electrode 210 having a large planar area, characteristics of the diode may be changed due to diffusion of the metal and mixture of Al of the common cathode electrode 210 and Au of the pad electrode 31. On the other hand, the cathode electrode 21 of the embodiment is an electrode individually surrounding each anode electrode 22, and the area of each cathode electrode 21 is smaller than that of the common cathode electrode 210, so that the diffusion of the metal is reduced. By reducing the width of the cathode electrode 21 so that the CR_{C} product becomes close to a minimum, the effect of reducing the diffusion of the metal is also obtained.

FIG. 12 is an SEM image of a bridge structure on an anode side. The bridge wiring 35 includes a first connecting portion 351 connected to the anode electrode 22, a second connecting portion 352 connected to the pad electrode 33, and a third connecting portion 353 connecting the first connecting portion 351 and the second connecting portion 352. More specifically, the first connecting portion 351 of the bridge wiring 35 is connected to the anode electrode 22 via the pad electrode 32, and the second connecting portion 352 is connected to the pad electrode 33 via the pad electrode 34. The cathode electrode 21 surrounds the circumference of the anode electrode 22, and the pad electrode 31 overlaps the cathode electrode 21.

The first connecting portion 351 and the second connecting portion 352 of the bridge wiring 35 have a cup shape having a recessed portion, and have a first opening 355 and a second opening 356, respectively. The third connecting portion 353 connects an edge 357 of the first opening 355 and an edge 358 of the second opening 356. By forming the first connecting portion 351 and the second connecting portion 352 at both ends of the bridge wiring 35 into a recessed structure, tensile stress and compressive stress when the entire diode 10 is covered with a protective film are relaxed. Thus, the first connecting portion 351 and the second connecting portion 352 hold the bridge wiring 35, and disconnection or short circuit can be prevented. In addition, a hollow structure at both ends of the bridge wiring 35 can reduce an increase in resistance due to a skin effect when a high-frequency signal flows.

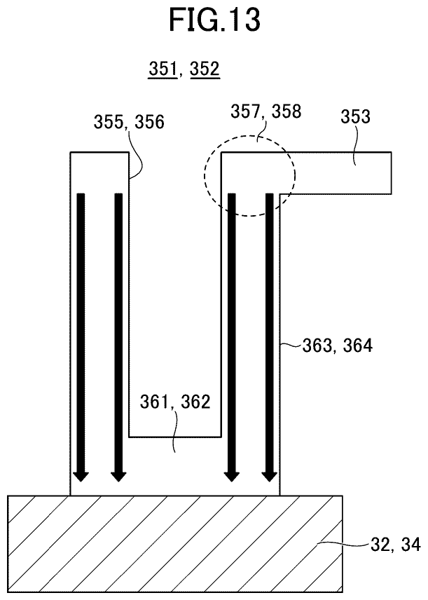

FIG. 13 is a schematic view of the first connecting portion 351 of the bridge wiring 35. The second connecting portion 352 has the same configuration as that of the first connecting portion 251 except that the connection direction is opposite to that of the first connecting portion 351 and the shape is slightly different. Consequently, the reference numerals of the constituent portions of the second connecting portion 352 corresponding to the constituent portions of the first connecting portion 351 are also used. The first connecting portion 351 is formed by a first bottom portion 361 and a first sidewall 363 surrounding the first bottom portion 361, and has a first opening 355 at an upper end of the first sidewall 363. The second connecting portion 352 is formed by a second bottom portion 362 and a second sidewall 364 surrounding the second bottom portion 362, and has a second opening 356 at an upper end of the second sidewall 364.

As illustrated in FIG. 13, when an electrode has an opening, and a current flows from a sidewall portion, and also when, for example, the thickness of the first sidewall 363 or the second sidewall 364 is in a range from 0.2 μm to 1 μm, the contribution of a skin effect increases in a frequency range from 20 GHz to 500 GHz. The skin effect is a phenomenon in which a current is less likely to flow as the distance from the surface of a conductor increases, and this phenomenon appears more prominently as the frequency increases. In the case of such a thickness range, an increase in electrical resistance when a current flows through the inner side and the outer side of the sidewall due to the skin effect can be reduced. In the example illustrated in FIG. 13, because the third connecting portion 353 is connected to the first sidewall 363, a current flows through the inner side and the outer side of the first sidewall 363. Consequently, a surface area through which a high-frequency current indicated by arrows flows is increased. For example, in a cylindrical via wiring portion in which an opening is filled, a current is concentrated on a surface of the cylinder and hardly flows inside the conductor, resulting in increase in resistance. On the other hand, in the first connecting portion 351 and the second connecting portion 352 of the bridge wiring 35, a current flows in a region along an outer wall and a region along an inner wall, and resistance can be reduced as compared with the general cylindrical conductor.

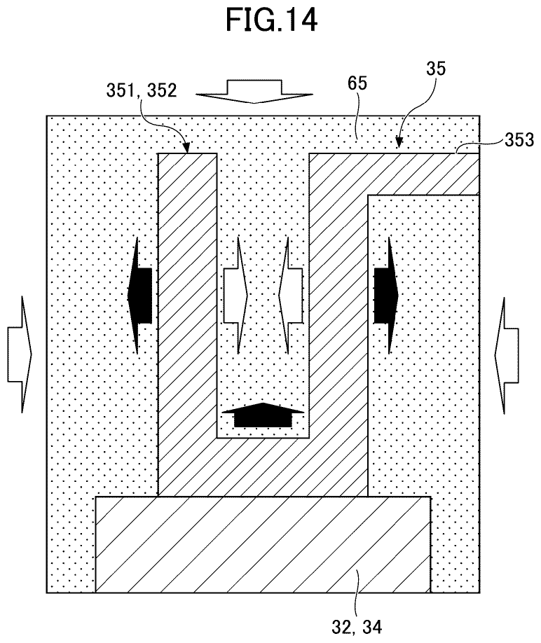

FIG. 14 illustrates the effect of maintaining the shape of the bridge wiring by the cup-shaped first opening 355 or second opening 356. When a protective film 65 formed of resin such as polyimide is formed onto the entire surfaces of the first opening 355, the second opening 356, and the bridge wiring 35 to serve as the protective film of the diode 10, the recessed portion of the first connecting portion 351 and the recessed portion of the second connecting portion 352 of the bridge wiring 35 are also filled with the protective film 65. Even when stress is applied to the first opening 355 or the second opening 356 due to a difference in thermal expansion coefficient between materials, compressive stress or tensile stress toward the inside of the first opening 355 or the second opening 356 and compressive stress or tensile stress toward the outside of the first connecting portion 351 and the second connecting portion 352 are relaxed and the first connecting portion 351 and the second connecting portion 352 hold the bridge wiring 35, so as to reduce disconnection and short circuit.

The diode 10 of the embodiment can suppress metal diffusion between the electrodes on the cathode side in addition to high-frequency characteristics due to the reduction of the CR_{C} product. In addition, on the anode side, the resistance of the bridge wiring 35 can be reduced, and deformation, disconnection, and falling of the bridge wiring 35 can be reduced.

### Manufacturing Process of Bridge Wiring

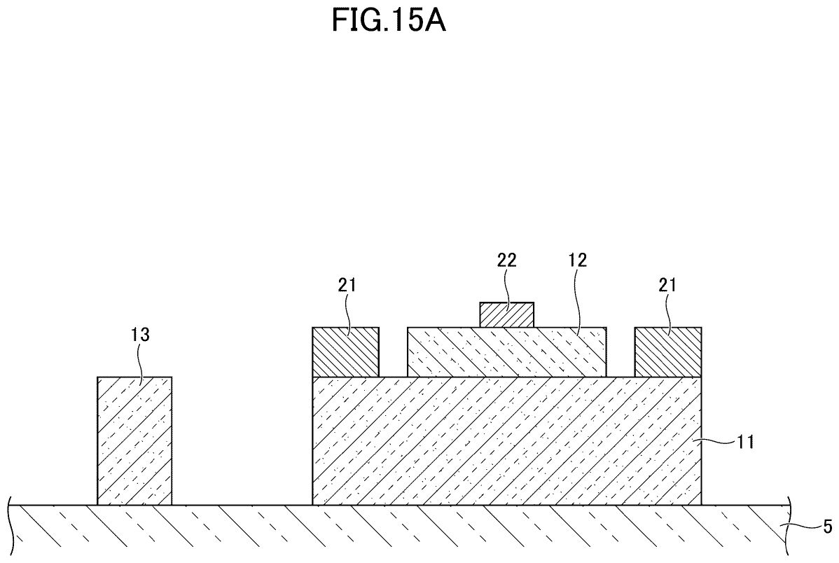

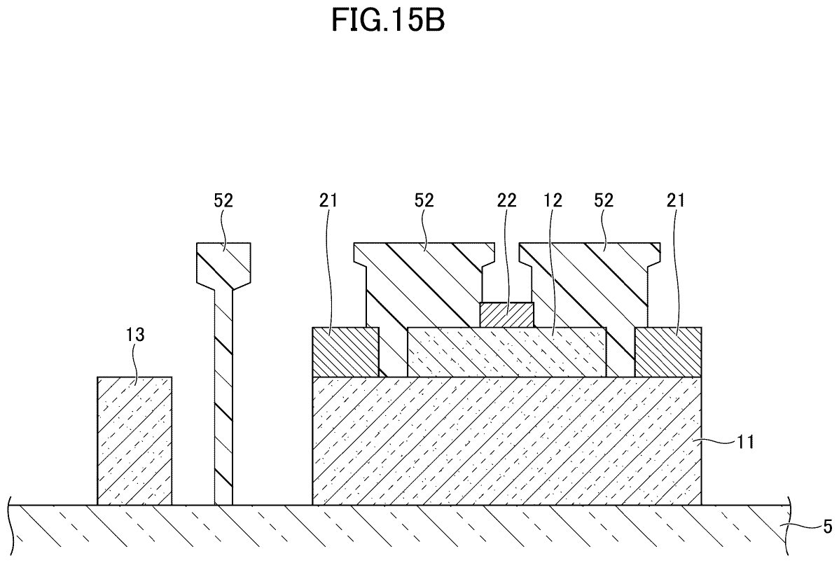

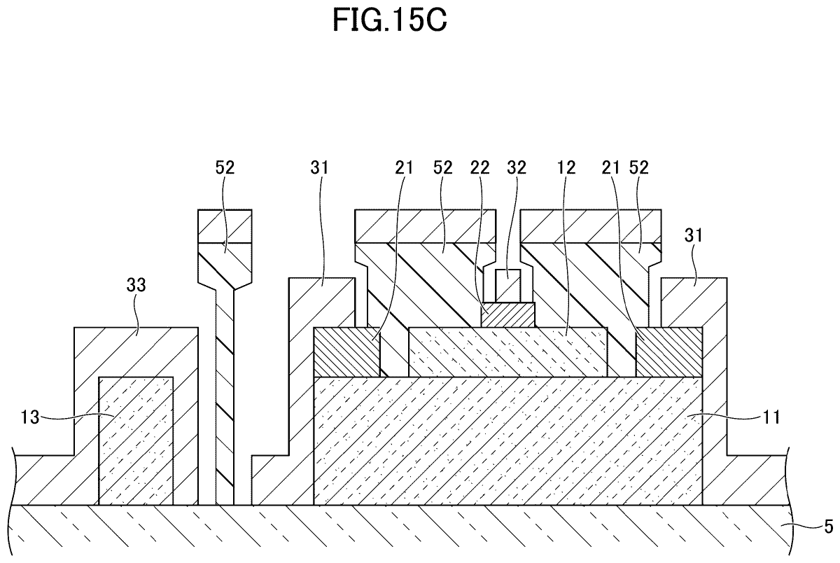

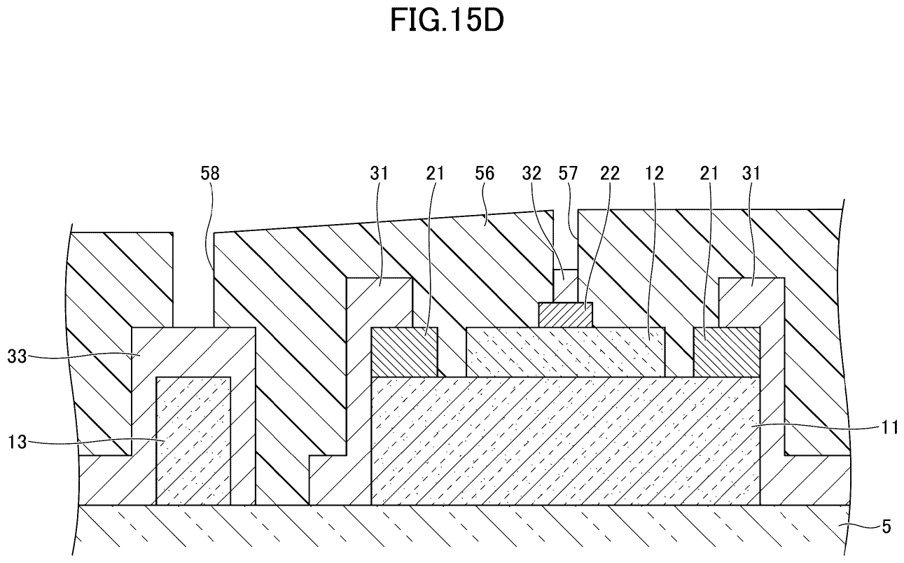

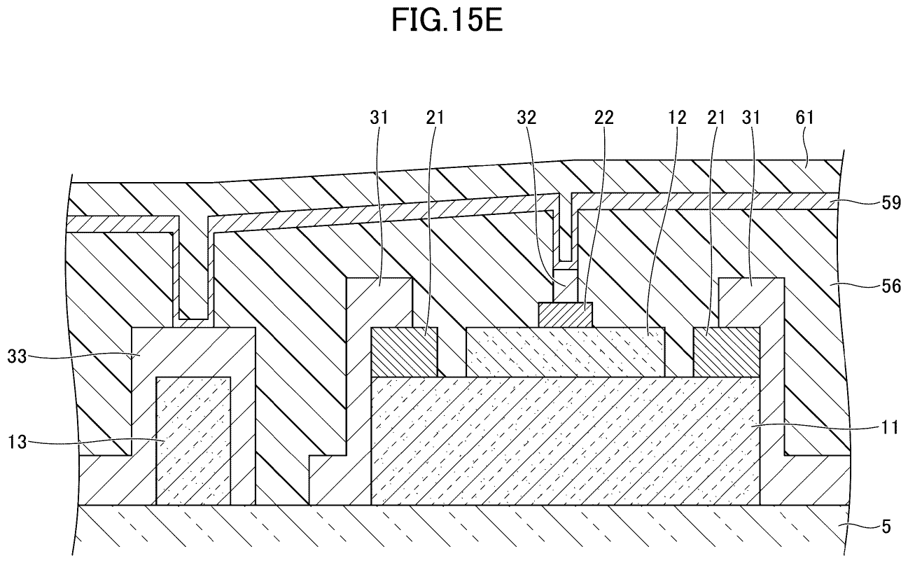

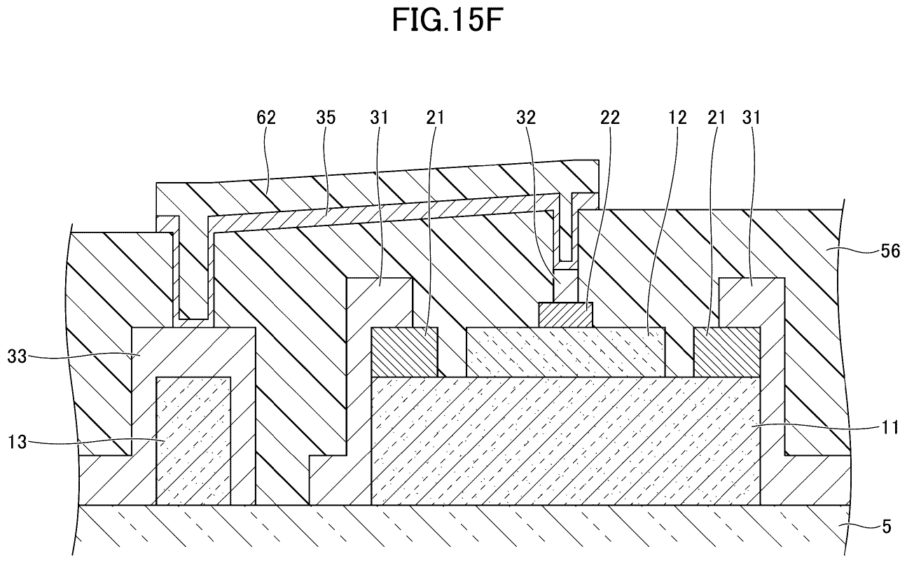

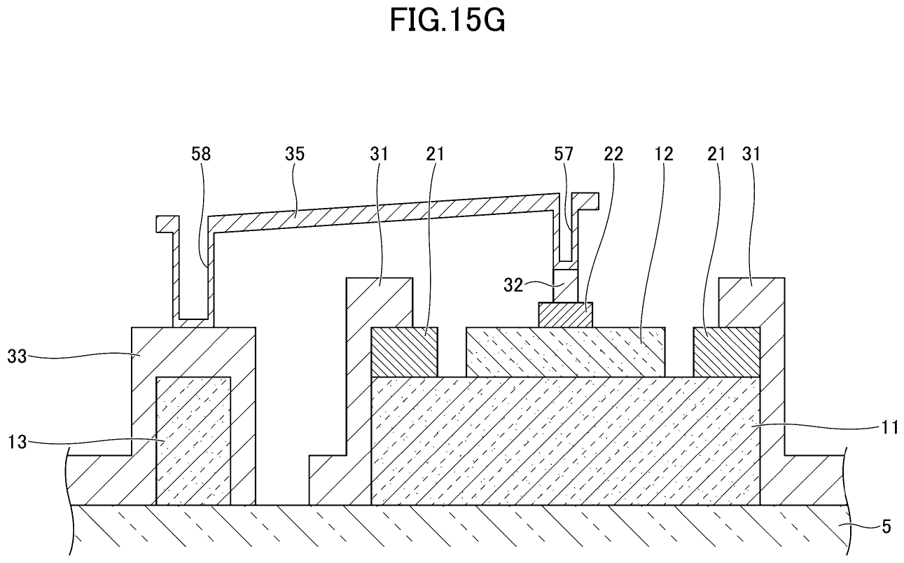

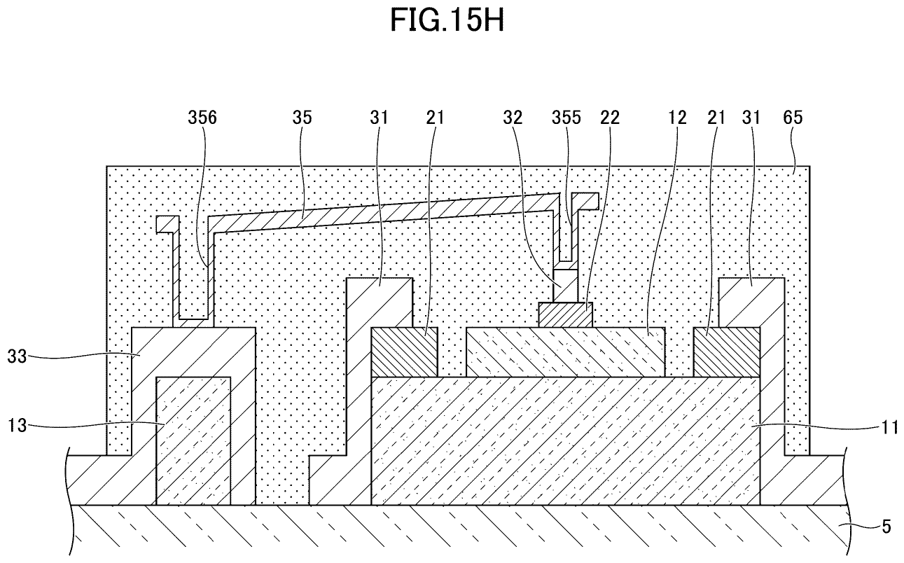

FIGS. 15A to 15H are manufacturing process views for the bridge wiring 35. FIG. 15A illustrates a state immediately before the bridge wiring 35 is formed. At this stage, the main part of the diode 10 including the cathode electrode 21 provided on the first semiconductor layer 11 and the anode electrode 22 provided on the second semiconductor layer 12 is formed. The cathode electrode 21 surrounds at least a part of the circumference of the second semiconductor layer 12 and has an annular or C-shaped planar shape. The width of the cathode electrode 21 in the radial direction is set in a range from one time to six times the propagation length Lₜ described above, and the CR product is reduced.

The third semiconductor layer 13 is formed in a region where the first semiconductor layer 11 is not provided. For example, the first semiconductor layer 11 and the third semiconductor layer 13 are formed by etching a semiconductor layer grown by a metal organic chemical vapor deposition method to separate the etched semiconductor layer into two layers, and the same impurity is introduced. Note that each of the components in FIG. 15A can be formed by a known process.

In FIG. 15B, a negative resist 52 is applied to the substrate 5, the first semiconductor layer 11, the second semiconductor layer 12, the third semiconductor layer 13, the cathode electrode 21, and the anode electrode 22, and through exposure while covering necessary portions and development of the resist, a mask is formed at desired positions. When the negative resist is exposed to light, for example, an opening having a portion expanding toward the anode electrode 22 is formed immediately above the anode electrode 22.

In FIG. 15C, a pad electrode 31 covering the upper surface and the lateral surface of the cathode electrode 21 and the lateral surface of the first semiconductor layer 11 is provided, and a pad electrode 33 covering the entire upper surface and lateral surface of the third semiconductor layer 13 is provided. The pad electrode 31 and the pad electrode 33 can be formed by the same process. In FIG. 15C, the exposed surfaces of the electrodes are cleaned, and then by sputtering, a conductive layer for the pad electrode 31 is formed on the cathode surface, a conductive layer for the pad electrode 33 is formed on the surface of the third semiconductor layer 13, and a conductive layer for the pad electrode 32 is formed inside an aperture 53. The conductive layer for the pad electrode 32 has a film configuration in which, for example, Ti, platinum (Pt), and Au are layered in this order. By forming the pad electrodes 31, 32, and 33, the anode electrode 22 can be protected and diffusion of an electrode material can be reduced when the diode is heated in a subsequent process to be described below.

After the conductive layers for the pad electrodes 31, 32, and 33 are formed, the resist 52 and the metal material adhering to the resist 52 are removed by lift-off. Thus, the pad electrode 32 connected to the anode electrode 22 is obtained.

In FIG. 15D, a positive resist 56 is applied to the substrate 5, the first semiconductor layer 11, the second semiconductor layer 12, the third semiconductor layer 13, the cathode electrode 21, the anode electrode 22, and the pad electrodes 31, 32, and 33, and necessary portions are exposed to light and developed to form apertures 57 and 58. The pad electrode 32 on the anode electrode 22 is exposed inside the aperture 57.

In FIG. 15E, a conductor film 59 is formed on an upper surface of the positive resist 56 and inside the apertures 57 and 58 by sputtering. The conductor film 59 is, for example, an Au film. By these processes, the first opening 355 and the second opening 356 are formed in the conductor film 59 on the pad electrode. Subsequently, a positive resist 61 is applied to an upper surface of the conductor film 59. The positive resist 61 is applied to fill the first opening 355 and the second opening 356. In FIG. 15F, light exposure is performed except for the region where the bridge wiring 35 is formed, and a resist mask 62 is formed. Subsequently, wet etching is performed using the resist mask 62 to remove a part of the conductor film 59. Thus, the bridge wiring 35 connected to the pad electrodes 32 and 33 at both ends thereof is formed. In FIG. 15G, the resist mask 62 and the positive resist 56 are stripped by a stripper solution. Thus, the diode 10 is obtained.

In FIG. 15H, the diode 10 is covered with the protective film 65 formed of polyimide or the like. The first semiconductor layer 11, the second semiconductor layer 12, the third semiconductor layer 13, the cathode electrode 21, the anode electrode 22, the pad electrodes 31 and 33, and the bridge wiring 35 are covered with the protective film 65. The protective film 65 fills inside the first opening 355 of the first connecting portion 351 of the bridge wiring 35, and also the second opening 356 of the second connecting portion 352, so that the bridge wiring 35 is stably held. The protective film 65 is formed by, for example, a spin coating method.

Through the processes described above, the diode 10 of the embodiment is formed. The diode 10 of the embodiment can be usefully applied to power transmission at a high frequency, energy harvesting, and the like, because the CR product of the diode 10 is reduced by reducing the CR_{C} product in the cathode electrode 21.

### Application Example of Diode

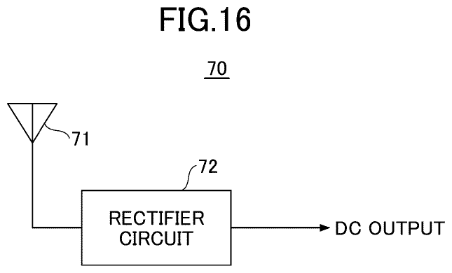

FIG. 16 is a schematic diagram of a power-receiving rectenna 70 to which the diode 10 of the embodiment is applied. The power-receiving rectenna 70 includes a power-receiving antenna 71 and a rectifier circuit 72. The rectifier circuit 72 includes the diode 10 of the embodiment. The power-receiving antenna 71 can receive electromagnetic waves in a range from 0.9 GHz to 500 GHz. The electromagnetic wave received by the power-receiving antenna 71 is rectified by the rectifier circuit 72 and is output as DC power. A stub line may be inserted on an input side of the rectifier circuit 72. Note that the rectifier circuit has capacitance. This capacitance smooths out a positive current that oscillates only in the positive direction. Thus, AC power is converted into DC power.

The present invention has been described based on the specific configuration example, but is not limited to the configuration example described above. As long as the width of the cathode electrode 21 is set in a range from one time to six times the propagation length Lₜ, the inner diameter of the cathode electrode 21, the diameter of the anode electrode 22, the distance between the anode electrode 22 and the cathode electrode 21, the impurity concentration of the second semiconductor layer 12, the breakdown voltage characteristics, and the like, can be appropriately designed. The material for the pad electrodes 31, 32, 33, and 34 can also be appropriately selected. The cross-sectional shapes of the first connecting portion 351 and the second connecting portion 352 of the bridge wiring 35 are appropriately designed to be a circle, an ellipse, a polygon, or the like. The first connecting portion 351 and the second connecting portion 352 have the first opening 355 and the second opening 356 corresponding to the cross-sectional shape thereof, respectively.

This application claims priority based on Japanese Patent Application No. 2023-013629, filed on Jan. 31, 2023, the entire contents of which are included herein by reference.

1. A diode comprising:
a substrate;
a first semiconductor layer provided on the substrate, the first semiconductor containing a first impurity at a first concentration;
a second semiconductor layer provided on the first semiconductor layer, the second semiconductor layer containing a second impurity at a concentration lower than the first concentration;
a first electrode provided on the first semiconductor layer, the first electrode surrounding at least a part of the second semiconductor layer; and
a second electrode provided on the second semiconductor layer,
wherein a width of the first electrode is in a range from one time to six times a propagation length Lₜ [m] as defined by Equation (1) set forth below:
$${L}_{t} [ m ] = {( ρc [ Ω \cdot {m}^{2} ] / Rs [ Ω / sq ] )}^{1 / 2} \qquad ( 1 )$$
where ρ_{C} is a contact resistivity between the first semiconductor layer and the first electrode, and R_{S} is a sheet resistance of the first semiconductor layer.

2. The diode according to claim 1, wherein the width of the first electrode is in a range from 1.5 times to 5 times the propagation length Lₜ [m].

3. The diode according to claim 1, wherein the first electrode surrounds an entire circumference of the second semiconductor layer.

4. The diode according to claim 1, comprising a pad electrode disposed on an upper surface and a lateral surface of the first electrode,
wherein the first electrode contains at least aluminum; and
the pad electrode contains at least gold.

5. The diode according to claim 1, comprising:
a third semiconductor layer provided in a region on the substrate where the first semiconductor layer is not provided, the third semiconductor layer containing the first impurity at the first concentration;
a third electrode provided on the third semiconductor layer; and
a bridge wiring configured to electrically connect the second electrode and the third electrode.

6. The diode according to claim 5, wherein
the bridge wiring comprises a first connecting portion connected to the second electrode, a second connecting portion connected to the third electrode, and a third connecting portion configured to connect the first connecting portion and the second connecting portion,
the first connecting portion comprises a first opening formed by a first bottom portion and a first sidewall surrounding the first bottom portion,
the second connecting portion comprises a second opening formed by a second bottom portion and a second sidewall surrounding the second bottom portion, and
the third connecting portion connects an edge of the first opening and an edge of the second opening.

7. The diode according to claim 5, comprising a protective film covering the first semiconductor layer, the second semiconductor layer, the third semiconductor layer, the first electrode, the second electrode, the third electrode, and the bridge wiring.

8. The diode according to claim 1, wherein the diode has rectification characteristics in a frequency range from 0.9 GHz to 500 GHz.

9. The diode according to claim 1, wherein a material for the first semiconductor layer and the second semiconductor layer is a nitride semiconductor.

10. The diode according to claim 1, comprising a Schottky barrier between the second semiconductor layer and the second electrode.

11. A rectifier circuit, comprising the diode according to claim 1.

12. A power-receiving rectenna comprising:
the rectifier circuit according to claim 11; and
a power-receiving antenna connected to the rectifier circuit.
